(19) United States
(12) Patent Application Publication
(10) Pub. No.: US 2018/0182658 A1
(43) Pub. Date: Jun. 28, 2018

(54) HORIZONTAL ARTICULATED ROBOT

(71) Applicant: KAWASAKI JUKOGYO KABUSHIKI KAISHA, Kobe-shi, Hyogo (JP)

(72) Inventors: Hirohiko GOTO, Akashi-shi (JP); Isao KATO, Nishinomiya-shi (JP); Masafumi KAMEDA, Kobe-shi (JP)

(73) Assignee: KAWASAKI JUKOGYO KABUSHIKI KAISHA, Kobe-shi, Hyogo (JP)

(21) Appl. No.: 15/577,137

(22) PCT Filed: May 25, 2015
(86) PCT No.: PCT/JP2015/002622

§ 371 Date: Nov. 27, 2017

(51) Int. Cl. H01L 21/687; B25J 9/04; B25J 9/16; B25J 15/00; B25J 11/00

(52) U.S. Cl. CPC H01L 21/68707; B25J 9/042; B25J 9/16; B25J 15/0014; Y10S 901/32; B25J 11/0095; Y10S 901/02; Y10S 901/23; Y10S 901/17; B25J 15/0028

(57) ABSTRACT

A horizontal articulated robot includes: a first link; a second link whose proximal end portion is coupled to one of an upper side and a lower side of a distal end portion of the first link; a third link whose proximal end portion is coupled to the other upper or lower side of a distal end portion of the second link; and a spacer disposed at a coupling position where the second link and one of the first link and the third link are coupled together, the spacer spacing the second link and the one link apart from each other in an up-down direction, such that a motion trajectory of the third link does not interfere with the first link.

### TECHNICAL FIELD

The present invention relates to the structure of a horizontal articulated robot including three links.

### BACKGROUND ART

Conventionally, substrate processing equipment for performing processing such as element formation on a semiconductor substrate, which is a semiconductor element manufacturing material, has been known (the term “semiconductor substrate” may be hereinafter simplified as “substrate”). In general, the substrate processing equipment includes, for example, a processing apparatus and a substrate transfer apparatus disposed at the front of the processing apparatus. The substrate transfer apparatus includes a substrate transfer robot that performs, for example, loading/unloading of the substrate into/from the processing apparatus and storing/retrieval of the substrate into/from a sealed carrier used for conveying the substrate between processes. For example, Patent Literature 1 discloses a substrate transfer apparatus (at the front end of line), which includes: an elongated casing with a small depth and a great width; and a substrate transfer robot configured to run on a path extending in the width direction (longitudinal direction) inside the casing.

At the front of the substrate transfer apparatus, a plurality of load ports are arranged in the width direction, which allows a plurality of carriers to be coupled to the single substrate transfer apparatus. In order to improve the throughput by coupling a larger number of carriers (e.g., four) to the single substrate transfer apparatus, the width of the substrate transfer apparatus needs to be great. Meanwhile, the depth of the substrate transfer apparatus is limited for the purpose of making the substrate transfer apparatus compact. For these reasons, the substrate transfer robot is required to fit within the limited depth of the substrate transfer apparatus and cover a work area that is wide in the width direction of the substrate transfer apparatus.

In order to meet the above requirements, conventionally, the robot is configured to be runnable in the width direction of the substrate transfer apparatus as in Patent Literature 1, or a plurality of robots are provided for a single substrate transfer apparatus.

However, if such a running path and a running machine are provided inside the casing of the substrate transfer apparatus, dust tends to be generated from them, and thereby the interior of the casing, which is to be kept clean, tends to become dirty. In addition, in a case where a plurality of robots are provided for a single substrate transfer apparatus, the initial and running costs and the apparatus size are increased. In view of these problems, Patent Literature 2 discloses providing a horizontal articulated robot with three links, thereby making the robot capable of accessing farther positions while avoiding the problems arising in the other techniques.

### CITATION LIST

### Patent Literature

PTL 1: Japanese Laid-Open Patent Application Publication No. 2002-76097

PTL 2: Japanese Laid-Open Patent Application Publication No. 2011-119556

### SUMMARY OF INVENTION

### Technical Problem

The horizontal articulated robot of Patent Literature 2 is configured such that a first link, a second link, and a third link are arranged upward in this order from the base side. In this case, the positional range accessible by the distal end portion of the third link (i.e., the positional range accessible by the wrist of the robot arm) is shifted upward compared to the positional range accessible by the wrist of a two-link robot arm. In order to make such a three-link horizontal articulated robot compatible with existing peripheral equipment such as the processing apparatus, it is necessary to make adjustments to the height of the peripheral equipment or the robot.

### Solution to Problem

In view of the above, a horizontal articulated robot according to one aspect of the present invention includes: a first link; a second link whose proximal end portion is coupled to one of an upper side and a lower side of a distal end portion of the first link; a third link whose proximal end portion is coupled to the other upper or lower side of a distal end portion of the second link; and a spacer disposed at a coupling position where the second link and one of the first link and the third link are coupled together, the spacer spacing the second link and the one link apart from each other in an up-down direction, such that a motion trajectory of the third link does not interfere with the first link.

According to the above horizontal articulated robot, the height of the distal end portion of the third link can be lowered compared to a case where the first to third links are sequentially arranged upward.

### Advantageous Effects of Invention

According to the present invention, the height of the distal end portion of the third link can be lowered compared to a case where the first to third links are sequentially arranged upward.

### BRIEF DESCRIPTION OF DRAWINGS

FIG. 1 is a plan view of substrate processing equipment for describing the usage mode of a horizontal articulated robot according to one embodiment of the present invention.

FIG. 2 is a side view showing a schematic configuration of the horizontal articulated robot according to the embodiment of the present invention.

FIG. 3 is a block diagram showing a control system configuration of the horizontal articulated robot.

FIG. 4 is a side view showing a schematic configuration of a horizontal articulated robot according to Variation 1.

FIG. 5 is a side view showing a schematic configuration of a horizontal articulated robot according to Variation 2.

FIG. 6 is a side view showing a schematic configuration of a horizontal articulated robot according to Variation 3.

### DESCRIPTION OF EMBODIMENTS

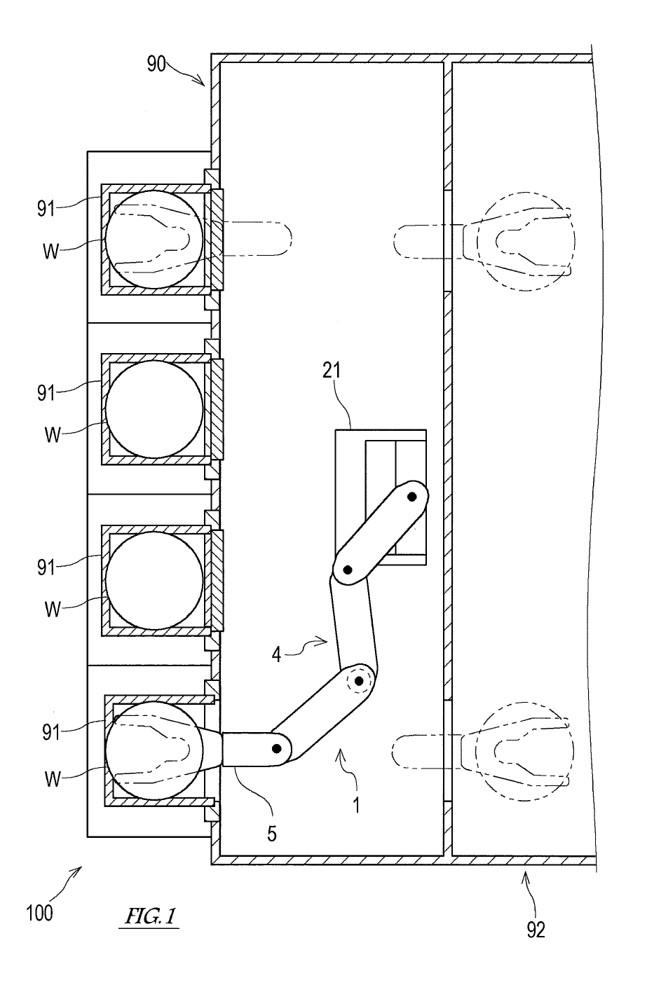

FIG. 1 is a plan view of substrate processing equipment 100 for describing the usage mode of a horizontal articulated robot 1 according to one embodiment of the present invention. As shown in FIG. 1, the substrate processing equipment 100 includes a processing apparatus 92 and a substrate transfer apparatus 90 disposed at the front of the processing apparatus 92. In the substrate processing equipment 100, the horizontal articulated robot 1 according to the present embodiment is included in the substrate transfer apparatus 90, and is used as a substrate transfer robot for performing, for example, loading/unloading of a substrate W into/from the processing apparatus 92 and storing/retrieval of the substrate W into/from a sealed carrier 91 used for conveying the substrate W between processes. An equipment front end module (abbreviated as EFEM) is known as one example of the substrate transfer apparatus 90. Also, a front opening unified pod (FOUP) is known as one example of the carrier 91. It should be noted that the usage of the horizontal articulated robot 1 is not limited to the above.

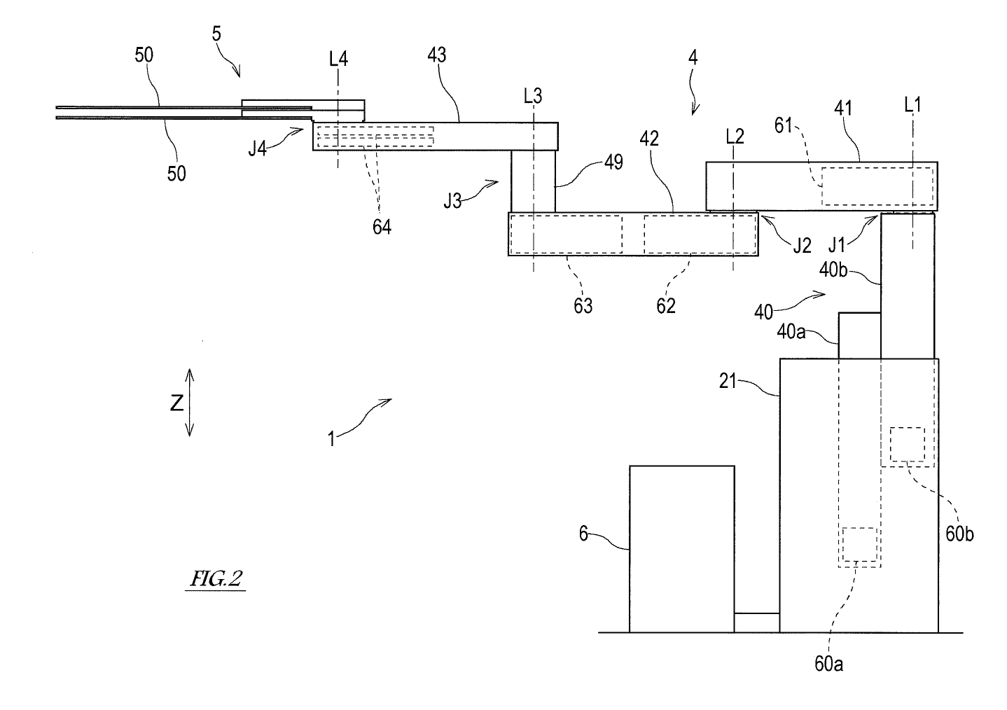

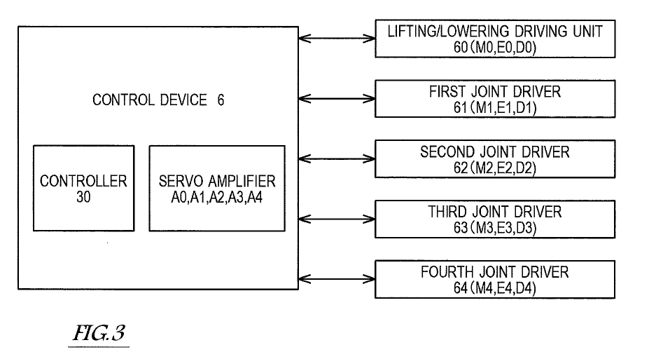

FIG. 2 is a side view showing a schematic configuration of the horizontal articulated robot 1 according to the embodiment of the present invention. FIG. 3 is a block diagram showing a control system configuration of the horizontal articulated robot 1. As shown in FIGS. 2 and 3, the horizontal articulated robot 1 according to the embodiment of the present invention includes the following main components: a base 21; a robot arm 4 supported by the base 21; an end effector 5 coupled to the wrist of the robot arm 4; and a control device 6 configured to control operations of the robot arm 4 and the end effector 5.

The robot arm 4 includes: a lifting/lowering shaft 40 supported by the base 21; a first link 41 coupled to the lifting/lowering shaft 40 via a first joint J1; a second link 42 coupled to the distal end portion of the first link 41 via a second joint J2; and a third link 43 coupled to the distal end portion of the second link 42 via a third joint J3.

The proximal end portion of the second link 42 is coupled to the lower side of the distal end portion of the first link 41. The proximal end portion of the third link 43 is coupled to the upper side of the distal end portion of the second link 42. The end effector 5 is coupled to the upper side of the distal end portion of the third link The third joint J3, at which the distal end portion of the second link 42 and the proximal end portion of the third link 43 are coupled together, is provided with a spacer 49, by which the second link 42 and the third link 43 are spaced apart from each other in an up-down direction Z.

The spacer 49 is hollow-shaft-shaped and extends in the up-down direction Z. The central axis of the hollow shaft shape substantially coincides with a third axis L3. The spacer 49 supports, inside its interior, a hollow shaft (not shown) via a bearing such that the hollow shaft, which transmits rotational power from a joint driver 63 described below to the third link 43, is rotatable. Pipes, wires, etc., are inserted through the inside of the hollow shaft.

The end effector 5 is coupled to the distal end portion of the third link 43 via a fourth joint J4 (wrist joint). Assume that the rotational axis of the first joint J1 is defined as a first axis L1, the rotational axis of the second joint J2 is defined as a second axis L2, the rotational axis of the third joint J3 is defined as the aforementioned third axis L3, and the rotational axis of the fourth joint J4 is defined as a fourth axis L4. In this case, the direction in which each of these axes extends is the up-down direction Z, which is a substantially vertical direction. Also, the direction in which each of the first to third links 41, 42, and 43 extends is a substantially horizontal direction substantially perpendicular to the up-down direction Z.

The lifting/lowering shaft 40 has a two-step structure including a first step portion 40a and a second step portion 40b, and is configured as a shaft capable of lifting, lowering, and extending. Each of the first step portion 40a and the second step portion 40b is a rectangular tubular member. The first step portion 40a and the second step portion 40b are arranged in parallel. It should be noted that the first step portion 40a and the second step portion 40b may form a telescopic structure.

The first step portion 40a is coupled to the base 21 via a linear motion mechanism (not shown) intended for linear motion in the up-down direction Z. The second step portion 40b is coupled to the first step portion 40a via a linear motion mechanism (not shown) intended for linear motion in the up-down direction Z. The lifting/lowering shaft 40 is driven by a lifting/lowering driving unit 60 to lift, lower, and/or extend in the up-down direction Z. The lifting/lowering driving unit 60 includes: a first lifting/lowering driver 60a configured to move the first step portion 40a in the up-down direction Z relative to the base 21; and a second lifting/lowering driver 60b configured to move the second step portion 40b in the up-down direction Z relative to the first step portion 40a. Each of the first and second lifting/lowering drivers 60a and 60b of the lifting/lowering driving unit 60 includes, for example, a servomotor M0, a position detector E0, and a power transmission mechanism D0 transmitting the motive power of the servomotor M0 to the lifting/lowering shaft 40.

The end effector 5 has a double-hand structure, in which two substrate transfer hands 50 are arranged one on top of the other in the up-down direction Z. Each substrate transfer hand 50 includes, for example: a fork-shaped blade on which a round and flat plate-shaped substrate W is to be placed; a holding claw for holding the substrate W placed on the blade; and a driving mechanism driving the holding claw. Each of the two substrate transfer hands 50 is independently and rotatably coupled to the third link 43 by the fourth joint J4.

The first to fourth joints J1 to J4 are provided with first to fourth joint drivers 61 to 64, respectively. The first to fourth joint drivers 61 to 64 drive the respective joints J1 to J4 to rotate about their rotational axes. The joint drivers 61 to 64 include, for example: servomotors M1 to M4; position detectors E1 to E4; and power transmission mechanisms D1 to D4 configured to transmit the motive power of the respective servomotors M1 to M4 to the corresponding links. Each of the power transmission mechanisms D1 to D4 may be, for example, a gear power transmission mechanism including a decelerator. At least part of the power transmission mechanisms D1 to D4 may include a belt transmission mechanism. Each of the position detectors E0 to E4 is configured as a rotary encoder, for example. The servomotors M0 to M4 can be driven independently of each other. When the servomotors M0 to M4 are driven, the position detectors E0 to E4 detect rotational positions of the output shafts of the respective servomotors M0 to M4.

The operation of the robot arm 4 is controlled by the control device 6. As shown in FIG. 3, the control device 6 includes a controller 30 and servo amplifiers A0 to A4 corresponding to the respective servomotors M0 to M4. The control device 6 performs servo control of moving the end effector 5 mounted on the wrist of the robot arm 4 along an intended path to place the end effector 5 in an intended pose (i.e., place the end effector 5 in an intended position and orientation in space).

The controller 30 is a computer that includes, for example, an arithmetic processing unit such as a microcontroller, CPU, MPU, PLC, DSP, ASIC, or FPGA, and a storage unit including a ROM and a RAM (which are not shown). Programs executed by the arithmetic processing unit, various fixed data, etc., are stored in the storage unit. In addition, teaching point data for controlling the operation of the robot arm 4, data regarding the shape and dimensions of the end effector 5, data regarding the shape and dimensions of the substrate W held by the end effector 5, and so forth are stored in the storage unit. The controller 30 performs processing for controlling the operation of the horizontal articulated robot 1 by reading out and executing software, such as the programs stored in the storage unit, by the arithmetic processing unit. It should be noted that the controller 30 may be configured as a single computer performing each processing by centralized control, or may be configured as a plurality of computers performing distributed control in cooperation with each other, thereby performing each processing.

The controller 30 calculates a target pose, which is an intended pose of the end effector 5 after the elapse of a predetermined control time, based on: the pose of the end effector 5 corresponding to the rotational positions detected by the respective position detectors E0 to E4; and the teaching point data stored in the storage unit. The controller 30 outputs a control command (position command) to each of the servo amplifiers A0 to A4, such that the end effector 5 is placed in the target pose after the predetermined control time has elapsed. Each of the servo amplifiers A0 to A4 supplies driving electric power to a corresponding one of the servomotors M0 to M4 based on the control command. With this configuration, the end effector 5 can be moved and placed in the intended pose. In the horizontal articulated robot 1 according to the present embodiment, the joints J1 to J4 are driven independently of each other. However, as an alternative, the joints J1 to J4 may include at least one joint configured to operate passively in accordance with the motion of the other joints.

In the robot arm 4 with the above-described configuration, the dimension of the third link 43 in the longitudinal direction is substantially equal to or greater than the dimension of the second link 42 in the longitudinal direction, and the dimension of the first link 41 in the longitudinal direction is slightly smaller than the dimensions of the second link 42 and the third link 43 in the longitudinal direction. A third link length (the horizontal distance between the third axis L3 and the fourth axis L4) is substantially equal to or longer than a second link length (the horizontal distance between the second axis L2 and the third axis L3), and a first link length (the horizontal distance between the first axis L1 and the second axis L2) is slightly shorter than the second link length and the third link length. In the robot arm 4, in which the dimension of each of the links 41, 42, and 43 in the longitudinal direction is thus defined, when the second link 42 rotates about the second axis L2 relative to the first link 41, the motion trajectories of the second link 42 and the third link 43 (i.e., three-dimensional regions that the second link 42 and the third link 43 pass through) party overlap the first link 41 when seen in a plan view. Also, when the third link 43 rotates about the third axis L3 relative to the second link 42, the motion trajectory of the third link 43 (i.e., a three-dimensional region that the third link 43 passes through) partly overlaps the first link 41 and the second link 42 when seen in a plan view.

For these reasons, the second link 42 and the third link 43 are spaced apart from each other in the up-down direction Z by the spacer 49, such that the motion trajectory of the third link 43 does not interfere with the first link 41. In other words, the dimension of the spacer 49 in the up-down direction Z is set such that when the second link 42 rotates about the second axis L2 relative to the first link 41, the motion trajectories of the second link 42 and the third link 43 do not interfere with the first link 41, and such that when the third link 43 rotates about the third axis L3 relative to the second link 42, the motion trajectory of the third link 43 does not interfere with the first link 41 and the second link 42.

It should be noted that, in the horizontal articulated robot 1 according to the present embodiment, the first link 41 is rotatable about the first axis L1 by 360 degrees. Although the second link 42 is rotatable about the second axis L2 relative to the first link 41, the range of rotation of the second link 42 is restricted so as to avoid interference between the lifting/lowering shaft 40 and the second link 42. The third link 43 is rotatable about the third axis by 360 degrees.

As described above, the horizontal articulated robot 1 according to the present embodiment includes: the first link 41; the second link 42, whose proximal end portion is coupled to the lower side of the distal end portion of the first link 41; the third link 43, whose proximal end portion is coupled to the upper side of the distal end portion of the second link 42; and the spacer, which is disposed at a coupling position where the second link 42 and one of the first link 41 and the third link 43 are coupled together. It should be noted that each of the first link 41, the second link 42, and the third link 43 is a link member extending in the horizontal direction. In the present embodiment, the third link 43, the first link 41, and the second link 42 are arranged downward in this order.

In the above-described horizontal articulated robot 1, one of the first link 41 and the third link 43 coupled to the second link 42 is spaced apart from the second link 42 in the up-down direction by the spacer 49, such that the motion trajectory of the third link 43 does not interfere with the first link 41. In the present embodiment, the spacer 49 is disposed at the coupling position where the second link 42 and the third link 43 are coupled together, and thereby the second link 42 and the third link 43 are spaced apart from each other in the up-down direction Z.

In the above-described horizontal articulated robot 1, the height accessible by the distal end portion of the third link 43 (i.e., the height accessible by the wrist of the robot arm 4) can be lowered compared to a case where the first link 41, the second link 42, and the third link 43 are sequentially arranged upward. Specifically, in the case where the first link 41, the second link 42, and the third link 43 are sequentially arranged upward, the positional range accessible by the wrist of the robot arm 4 is shifted upward by the height of the third link 43 as compared to a two-link robot arm. However, the present invention makes it possible to avoid such a shift of the accessible positional range. Therefore, in the existing substrate processing equipment 100, the horizontal articulated robot 1 according to the present embodiment can be installed instead of an existing two-link robot arm without making changes to the existing peripheral equipment such as the processing apparatus 92.

The robot arm 4 of the above-described horizontal articulated robot 1 includes the three links, i.e., the first link 41, the second link 42, and the third link 43. Therefore, the stroke of the wrist of the robot arm 4 in the horizontal direction is longer than the stroke of the wrist of a two-link robot arm in the horizontal direction by one link. Therefore, the horizontal articulated robot 1 according to the present embodiment is suitable for operating within a long and narrow work area (i.e., a work area with a small depth and a great width), such as the substrate transfer apparatus 90.

The horizontal articulated robot 1 according to the above-described embodiment further includes the end effector 5, whose proximal end portion is coupled to the upper side of the distal end portion of the third link 43.

Accordingly, the motion trajectory of the end effector 5 does not overlap the motion trajectories of the third link 43 and the second link 42. This makes it possible to avoid interference of the end effector 5 with the second link 42 and the third link 43.

In particular, in the horizontal articulated robot 1 according to the present embodiment, the third link 43 is positioned above the other links 41 and 42. Therefore, motion of the end effector 5, which is coupled to the upper side of the distal end portion of the third link 43, is not hindered by the other two links 41 and 42.

Although the preferred embodiment of the present invention is as described above, the above-described configuration can be modified, for example, as described below.

The manner of coupling the links of the horizontal articulated robot 1 is not limited to the above-described embodiment. That is, it will suffice if the proximal end portion of the second link 42 is coupled to one of the upper side and the lower side of the distal end portion of the first link 41; the proximal end portion of the third link 43 is coupled to the other upper or lower side of the distal end portion of the second link 42; and the spacer 49 is disposed at the coupling position where the second link 42 and one of the first link 41 and the third link 43 are coupled together.

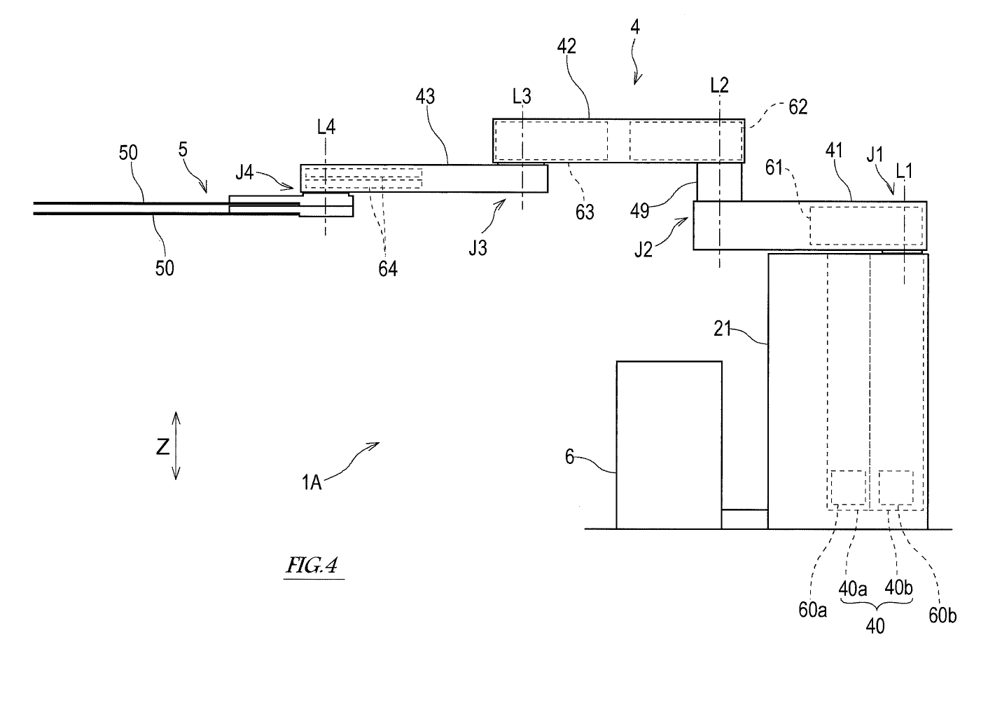

As one example, in a horizontal articulated robot 1A according to Variation 1 shown in FIG. 4, the proximal end portion of the second link 42 is coupled to the upper side of the distal end portion of the first link 41; the proximal end portion of the third link 43 is coupled to the lower side of the distal end portion of the second link 42; and the end effector 5 is coupled to the lower side of the distal end portion of the third link. The second joint J2, at which the distal end portion of the first link 41 and the proximal end portion of the second link 42 are coupled together, is provided with the spacer 49, by which the first link 41 and the second link are spaced apart from each other in the up-down direction Z.

In the horizontal articulated robot 1A with the above-described configuration, the dimension of the third link 43 in the longitudinal direction is substantially equal to or greater than the dimension of the second link 42 in the longitudinal direction, and the dimension of the first link 41 in the longitudinal direction is slightly smaller than the dimensions of the second link 42 and the third link 43 in the longitudinal direction. The third link length is substantially equal to or longer than the second link length, and the first link length is slightly shorter than the second link length and the third link length. In the horizontal articulated robot 1A, in which the dimension of each of the links 41, 42, and 43 in the longitudinal direction is thus defined, when the second link 42 rotates about the second axis L2 relative to the first link 41, the motion trajectories of the second link 42 and the third link 43 partly overlap the first link 41 when seen in a plan view. Also, when the third link 43 rotates about the third axis L3 relative to the second link 42, the motion trajectory of the third link 43 partly overlaps the first link 41 and the second link 42 when seen in a plan view.

For these reasons, the first link 41 and the second link 42 are spaced apart from each other in the up-down direction Z by the spacer 49. The dimension of the spacer 49 in the up-down direction Z is set such that when the second link 42 rotates about the second axis L2 relative to the first link 41, the motion trajectories of the second link 42 and the third link 43 do not interfere with the first link 41, and such that when the third link 43 rotates about the third axis L3 relative to the second link 42, the motion trajectory of the third link 43 does not interfere with the first link 41 and the second link 42.

It should be noted that, in the horizontal articulated robot 1 according to Variation 1, the first link 41 is rotatable about the first axis L1 by 360 degrees. The second link 42 is rotatable about the second axis L2 relative to the first link 41. Although the third link 43 is rotatable about the third axis, the range of rotation of the third link 43 is restricted so as to avoid interference between the spacer 49 and the third link 43.

As described above, the second link 42, the third link 43, and the first link 41 of the horizontal articulated robot 1A according to Variation 1 are arranged downward in this order. Therefore, assuming that a two-link robot arm serving as a comparative example includes the first link 41 and the third link 43, the position of the distal end portion of the third link 43 of the horizontal articulated robot 1A (i.e., the position of the wrist of the robot aim 4) in the up-down direction Z can be lowered to substantially the same position as the position of the wrist of the comparative robot arm in the up-down direction Z.

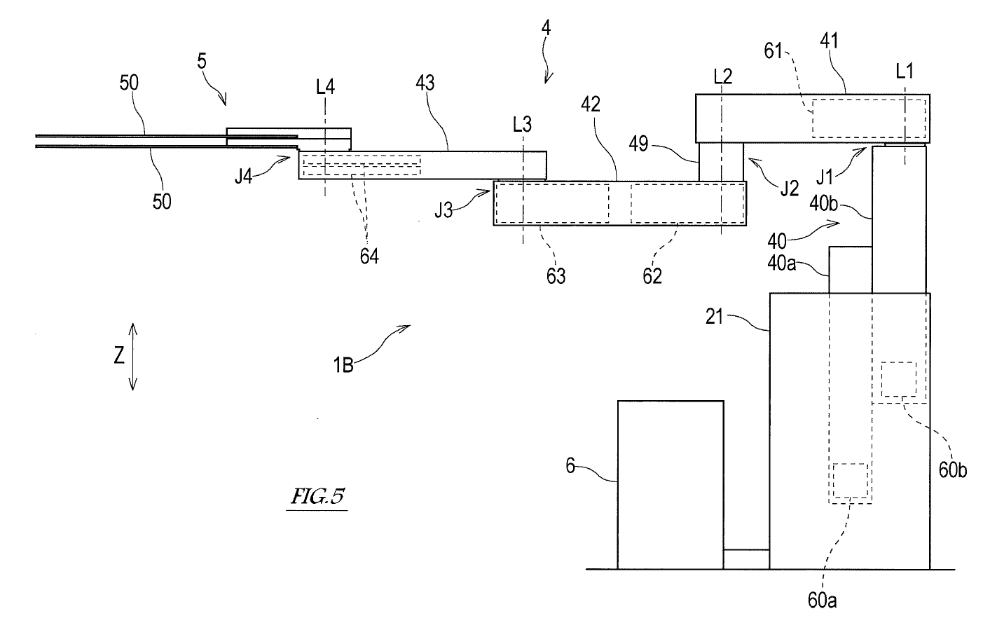

As another example, in a horizontal articulated robot 1B according to Variation 2 shown in FIG. 5, the proximal end portion of the second link 42 is coupled to the lower side of the distal end portion of the first link 41; the proximal end portion of the third link 43 is coupled to the upper side of the distal end portion of the second link 42; and the end effector 5 is coupled to the upper side of the distal end portion of the third link. The second joint J2, at which the distal end portion of the first link 41 and the proximal end portion of the second link 42 are coupled together, is provided with the spacer 49, by which the first link 41 and the second link 42 are spaced apart from each other in the up-down direction Z.

In the horizontal articulated robot 1B with the above-described configuration, the dimension of the third link 43 in the longitudinal direction is substantially equal to or greater than the dimension of the second link 42 in the longitudinal direction, and the dimension of the first link 41 in the longitudinal direction is slightly smaller than the dimensions of the second link 42 and the third link 43 in the longitudinal direction. The third link length is substantially equal to or longer than the second link length, and the first link length is slightly shorter than the second link length and the third link length. In the horizontal articulated robot 1B, in which the dimension of each of the links 41, 42, and 43 in the longitudinal direction is thus defined, when the second link 42 rotates about the second axis L2 relative to the first link 41, the motion trajectories of the second link 42 and the third link 43 partly overlap the first link 41 when seen in a plan view. Also, when the third link 43 rotates about the third axis L3 relative to the second link 42, the motion trajectory of the third link 43 partly overlaps the first link 41 and the second link 42 when seen in a plan view.

For these reasons, the first link 41 and the second link 42 are spaced apart from each other in the up-down direction Z by the spacer 49. The dimension of the spacer 49 in the up-down direction Z is set such that when the second link 42 rotates about the second axis L2 relative to the first link 41, the motion trajectories of the second link 42 and the third link 43 do not interfere with the first link 41, and such that when the third link 43 rotates about the third axis L3 relative to the second link 42, the motion trajectory of the third link 43 does not interfere with the first link 41 and the second link 42.

It should be noted that, in the horizontal articulated robot 1B according to Variation 2, the first link 41 is rotatable about the first axis L1 by 360 degrees. Although the second link 42 is rotatable about the second axis L2 relative to the first link 41, the range of rotation of the second link 42 is restricted so as to avoid interference between the lifting/lowering shaft 40 and the second link 42. Although the third link 43 is rotatable about the third axis, the range of rotation of the third link 43 is restricted so as to avoid interference between the spacer 49 and the third link 43.

As described above, the first link 41, the third link 43, and the second link 42 of the horizontal articulated robot 1B according to Variation 2 are arranged downward in this order. Therefore, the position of the distal end portion of the third link 43 of the horizontal articulated robot 1B (i.e., the position of the wrist of the robot arm 4) in the up-down direction Z can be lowered to the position of the first link 41 in the up-down direction Z, or can be lowered even further.

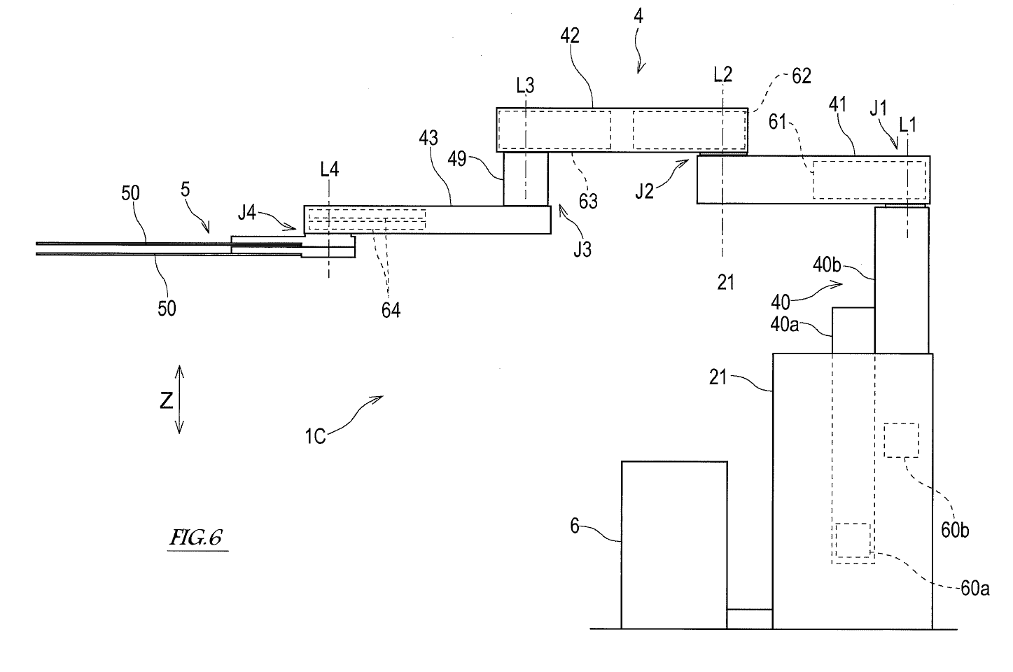

As yet another example, in a horizontal articulated robot 1C according to Variation 3 shown in FIG. 6, the proximal end portion of the second link 42 is coupled to the upper side of the distal end portion of the first link 41; the proximal end portion of the third link 43 is coupled to the lower side of the distal end portion of the second link 42; and the end effector 5 is coupled to the lower side of the distal end portion of the third link The third joint J3, at which the distal end portion of the second link 42 and the proximal end portion of the third link 43 are coupled together, is provided with the spacer 49, by which the second link 42 and the third link 43 are spaced apart from each other in the up-down direction Z.

In the horizontal articulated robot 1C with the above-described configuration, the dimension of the third link 43 in the longitudinal direction is substantially equal to or greater than the dimension of the second link 42 in the longitudinal direction, and the dimension of the first link 41 in the longitudinal direction is slightly smaller than the dimensions of the second link 42 and the third link 43 in the longitudinal direction. The third link length is substantially equal to or longer than the second link length, and the first link length is slightly shorter than the second link length and the third link length. In the horizontal articulated robot 1C, in which the dimension of each of the links 41, 42, and 43 in the longitudinal direction is thus defined, when the second link 42 rotates about the second axis L2 relative to the first link 41, the motion trajectories of the second link 42 and the third link 43 partly overlap the first link 41 when seen in a plan view. Also, when the third link 43 rotates about the third axis L3 relative to the second link 42, the motion trajectory of the third link 43 partly overlaps the first link 41 and the second link 42 when seen in a plan view.

For these reasons, the third link 43 and the second link 42 are spaced apart from each other in the up-down direction Z by the spacer 49. The dimension of the spacer 49 in the up-down direction Z is set such that when the second link 42 rotates about the second axis L2 relative to the first link 41, the motion trajectories of the second link 42 and the third link 43 do not interfere with the first link 41, and such that when the third link 43 rotates about the third axis L3 relative to the second link 42, the motion trajectory of the third link 43 does not interfere with the first link 41 and the second link 42.

It should be noted that, in the horizontal articulated robot 1C according to Variation 3, the first link 41 is rotatable about the first axis L1 by 360 degrees. Although the second link 42 is rotatable about the second axis L2 relative to the first link 41, the range of rotation of the second link 42 is restricted so as to avoid interference between the spacer 49 and the first link 41. Although the third link 43 is rotatable about the third axis, the range of rotation of the third link 43 is restricted so as to avoid interference between the end effector 5 and the lifting/lowering shaft 40.

As described above, the second link 42, the first link 41, and the third link 43 of the horizontal articulated robot 1C according to Variation 3 are arranged downward in this order. Therefore, the position of the distal end portion of the third link 43 of the horizontal articulated robot 1C (i.e., the position of the wrist of the robot arm 4) in the up-down direction Z can be lowered to the position of the first link 41 in the up-down direction Z, or can be lowered even further.

Although the description of the embodiment (and its variations) of the present invention has been given as above, numerous modifications and other embodiments of the present invention are obvious to a person skilled in the art. Therefore, the foregoing description should be interpreted only as an example and is provided for the purpose of teaching the best mode for carrying out the present invention to a person skilled in the art. The structural and/or functional details may be substantially altered without departing from the spirit of the present invention.

### REFERENCE SIGNS LIST

1 horizontal articulated robot

4 robot arm

5 end effector

6 control device

21 base

30 controller

40 lifting/lowering shaft

41 first link

42 second link

42 third link

49 spacer

60 lifting/lowering driving unit

61 to 64 joint drivers

90 substrate transfer apparatus

91 carrier

92 processing apparatus

100 substrate processing equipment

A0 to A4 servo amplifiers

D0 to D4 power transmission mechanisms

E0 to E4 position detectors

J1 to J4 first to fourth joints

L1 to L4 first to fourth axes

M0 to M4 servomotors

W substrate

1. A horizontal articulated robot comprising:
a first link;
a second link whose proximal end portion is coupled to one of an upper side and a lower side of a distal end portion of the first link;
a third link whose proximal end portion is coupled to the other upper or lower side of a distal end portion of the second link; and
a spacer disposed at a coupling position where the second link and one of the first link and the third link are coupled together, the spacer spacing the second link and the one link apart from each other in an up-down direction, such that a motion trajectory of the third link does not interfere with the first link.

2. The horizontal articulated robot according to claim 1, wherein
the spacer is hollow-shaft-shaped.

3. The horizontal articulated robot according to claim 1, further comprising an end effector whose proximal end portion is coupled to the other upper or lower side of a distal end portion of the third link.

4. The horizontal articulated robot according to claim 1, wherein
the third link, the first link, and the second link are arranged downward in this order, and
the spacer is disposed at the coupling position where the second link and the third link are coupled together.

5. The horizontal articulated robot according to claim 1, wherein
the second link, the third link, and the first link are arranged downward in this order, and
the spacer is disposed at the coupling position where the first link and the second link are coupled together.

6. The horizontal articulated robot according to claim 1, wherein
the first link, the third link, and the second link are arranged downward in this order, and
the spacer is disposed at the coupling position where the first link and the second link are coupled together.

7. The horizontal articulated robot according to claim 1, wherein
the second link, the first link, and the third link are arranged downward in this order, and
the spacer is disposed at the coupling position where the second link and the third link are coupled together.
